(19) United States
(12) Patent Application Publication
(10) Pub. No.: US 2002/0076956 A1
(43) Pub. Date: Jun. 20, 2002

(54) Electrical connector

(76) Inventor: Fumio Yuzawa, Matsumoto (JP)

Correspondence Address: Tyco Technology Resources, Suite 450, 4550 New Linden Hill Road, Wilmington, DE, 19808, US

(21) Appl. No.: 09/966,134

(22) Filed: Sep. 28, 2001

(30) Foreign Application Priority Data
Oct. 2, 2000 (JP) 2000-302573

(51) Int. Cl. H05K 1/00

(52) U.S. Cl. 439/79

(57) ABSTRACT

An electrical connector having an input-output connector part that is connected to an external connector and a power supply connector part that is connected to a power supply. The input-output connector part and the power supply connector part are formed into an integral unit by means of a common connector housing. The power supply connector part is divided and disposed on both sides of the input-output connector part as an integral part of the input-output connector part. The power supply connector part has tab contacts fastened to the connector housing. The tab contacts contact the power supply terminals of the power supply and are connected to a circuit board.

### BACKGROUND OF THE INVENTION

The present invention relates to an electrical connector, and more particularly, to an electrical connector having an input-output connector part that is connected to an external connector and a power supply connector part that is connected to a power supply.

### DESCRIPTION OF THE PRIOR ART

A conventional electrical connector, commonly used in portable telephones, has an input-output connector part that is connected to an external connector and a power supply connector part that is connected to a power supply. The electrical connector is mounted on an end portion of a circuit board that is disposed inside the body of a portable telephone.

One embodiment of a conventional electrical connector of this type is disclosed in Japanese Patent Application Kokai No. H9-63716 (FIG. 9). The electrical connector 100 of this embodiment has a power supply connector part 120 that has a connector housing 121 in common with the connector housing 111 of the input-output connector part 110, forming an integral unit with the input-output connector part 110. The power supply connector part 120 is offset to one side with respect to the input-output connector part 110. A plurality of power supply contacts 122 are disposed on the connector housing 121 and are arranged in a row at a specified pitch along the direction of length. The power supply contacts 122 are leaf-type contacts, each of which has a board connection part (not shown) connected to the circuit board. An elastic contact part 122a is bent and extended from the board connection parts, and elastically contacts a power supply terminal of a battery by means of a rolled surface.

Because the power supply connector part 120 is offset to one side with respect to the input-output connector part 110, the power supply contacts 122 that are used to fasten the electrical connector 100 to the circuit board are also offset to one side with respect to the signal contacts 114 and coaxial connector parts 115. This arrangement causes the balance of the electrical connector 100 to be unstable. In cases where an external force is applied to the electrical connector 100, as a result of an impact or torsion, etc., the board connection or solder connection parts connecting the signal contacts 114 and coaxial connector parts 115 to the circuit board are likely to be damaged by the external force.

Because the power supply contacts 122 are leaf-type contacts, the contacts 122 are also susceptible to damage. The contact pressure between the contacts and the power supply terminals of the battery may drop as a result of looseness of the battery in the vertical direction. Moreover, since the power supply contacts 122 and power supply terminals of the battery contact each other at a single contact point, the reliability of this contact is low.

It is desirable to develop an electrical connector in which the power supply connector part is stable with respect to the input-output connector part. When the electrical connector is balanced, the board connection parts of the contacts located in the input-output connector part are sufficiently protected, and the reliability of the contact between the contacts located in the power supply connector part and the power supply terminals on the power supply side is improved.

### SUMMARY OF THE INVENTION

This invention relates to an electrical connector having an input-output connector part that is connected to an external connector and a power supply connector part that is connected to a power supply. The input-output connector part and the power supply connector part are formed into an integral unit by means of a common connector housing. The power supply connector part is divided and disposed on both sides of the input-output connector part as an integral part of the input-output connector part. The power supply connector part has tab contacts fastened to the connector housing. The tab contacts contact the power supply terminals of the power supply and are connected to a circuit board.

### BRIEF DESCRIPTION OF THE DRAWINGS

The invention will now be described by way of example with reference to the accompanying figures wherein:

FIG. 1 is a partial perspective view of the electrical connector incorporated into a portable telephone prior to the connection of an internal battery to the electrical connector.

FIG. 2 is a perspective view of the top of the electrical connector.

FIG. 3 is a perspective view of the bottom of the electrical connector.

FIG. 4 is a top view of the electrical connector.

FIG. 5 is a front view of the electrical connector.

FIG. 6 is a bottom view of the electrical connector.

FIG. 7 is a right-side view of the electrical connector.

FIG. 8 is a rear view of the electrical connector.

FIG. 9 is a perspective view of a conventional electrical connector known in the prior art.

### DETAILED DESCRIPTION OF THE PREFERRED EMBODIMENT

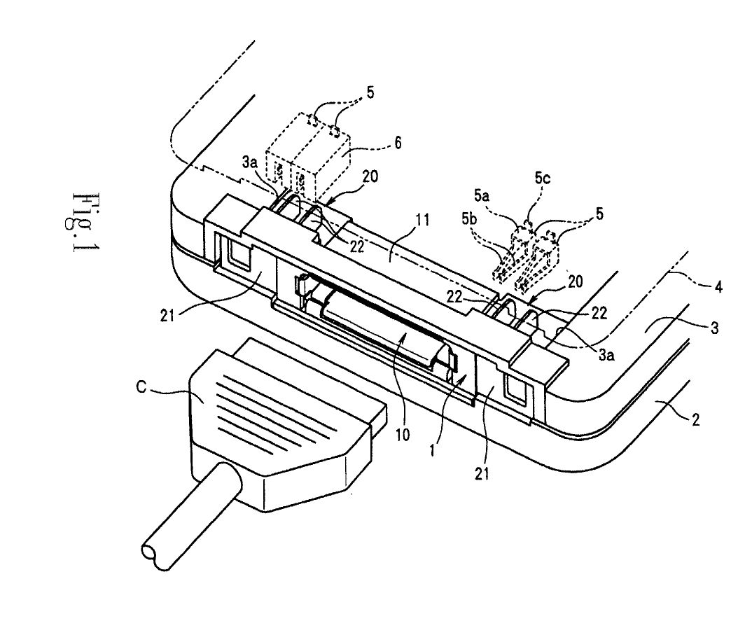

FIG. 1 shows an electrical connector 1 accommodated inside a housing 3 in a casing 2 of a portable telephone. The electrical connector 1 is mounted on an end portion of a circuit board (not shown) which is installed inside the housing 3. The electrical connector 1 has an input-output connector part 10 and a power supply connector part (20). The input-output connector part 10 is connected to an external connector C that is connected to an external device, such as a notebook-type personal computer, via a cable. The power supply connector part 20 is connected to a power supply, such as a battery or battery pack, contained in the cover 4 of the portable telephone.

The battery (not shown in FIG. 1) is arranged so that four power supply terminals 5 disposed in the housing 6 of the battery contact four tab contacts 22 of the power supply connector part 20. Each of the power supply terminals 5 has a base part 5a C-shaped in cross-section and a pair of elastic contact parts 5b. The elastic contact parts 5b extend forward from the base parts 5a and clamp a tab contact 22 between each other. Each of the power supply terminals also has a connecting terminal part 5c that extends upward from the rear end of the base part 5a. The accommodation space of the battery housing 6 is demarcated by the inner wall 3a of the housing 3 of the portable telephone and the outer surface of the connector housing 1, so that the power supply terminals 5 can contact the tab contacts 22.

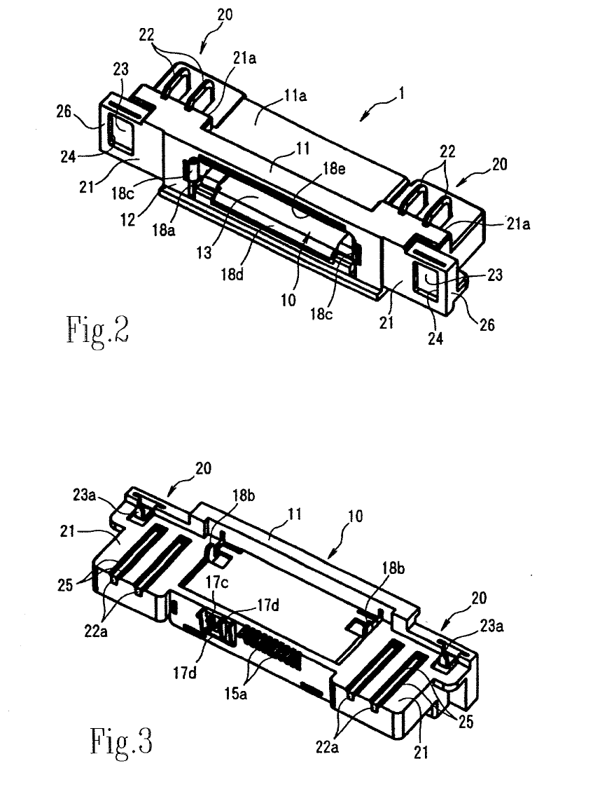

The input-output connector part 10 has an insulating connector housing 11 (FIGS. 2 and 5). The connector housing 11 has an external connector accommodating recess 13 that extends in the direction of length (i.e., the left-right direction in FIG. 2) in the front surface 12 of the housing 11. A step part 11a is formed in the connector housing 11 that opens on the upper surface and rear surface. Disposed inside the external connector accommodating recess 13, is a signal connector part 16 and a coaxial connector part 17 (FIG. 5). The coaxial connector part 17 is disposed to one side of the signal connector part 16. The signal connector part 16 extends from the connector housing 11 and has a plurality of signal contacts 15 lined up at a specified pitch on a flat-plate part 14.

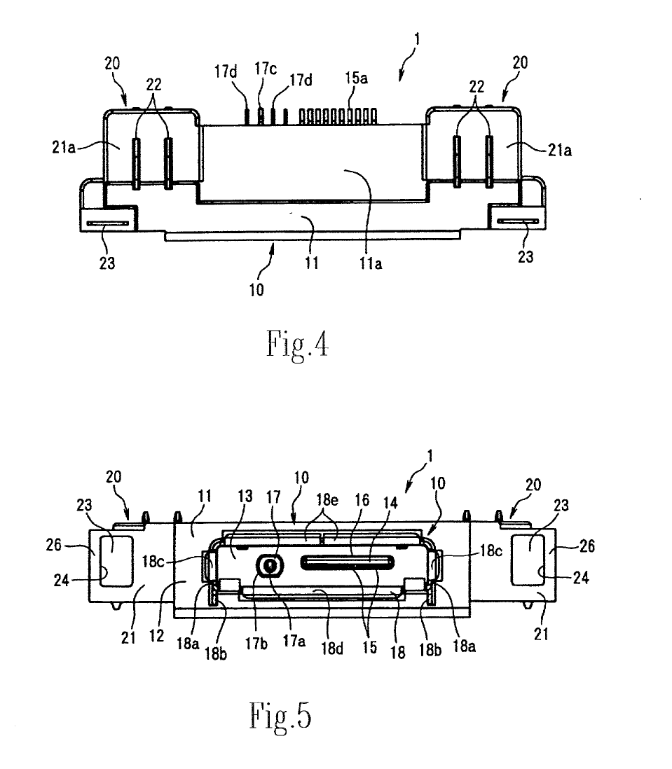

The respective signal contacts 15 are connected by soldering tine parts 15a that protrude rearward from the connector housing 11 to signal conductive paths on the circuit board (FIGS. 3 and 4). Soldering a tine part 17c that protrudes rearward from the connector housing 11 to the circuit board connects the internal conductor 17a of the coaxial connector part 17. The external conductor 17b is connected by soldering by a tine part 17d that protrudes rearward from the connector housing 11 to the circuit board.

A shielding shell 18, made of metal and formed by stamping and bending a metal plate, is disposed in the external connector accommodating recess 13 (FIG. 5). The shielding shell 18 is fastened to the peripheral edge of the external connector accommodating recess 13 by press-fitting from the front so that the shell 18 covers the signal connector part 16 and coaxial connector part 17.

A pair of retention legs 18b extend downward on both side walls 18a with respect to the direction of length. The retention legs 18b are soldered to the grounding path of the circuit board in order to ground the shielding shell 18. The retention legs 18b reinforce the electrical connector 1 when the electrical connector 1 is fastened to the circuit board.

A pair of external connector introduction guide parts 18c are bent and folded to the outside and are disposed on the front ends of both sidewalls 18a of the shielding shell 18. An external connector introduction guide part 18d is bent and folded downward and is disposed on the front end of the lower wall. External connector introduction guide parts 18e are bent and folded upward and are disposed on the front end of the upper wall. Thus, in addition to the function of shielding the signal connector part 16 and coaxial connector part 17, the shielding shell 18 also has the function of reinforcing the relatively thin upper wall that demarcates the external connector accommodating recess 13.

The power supply connector part 20 is uniformly divided and disposed on both sides of the input-output connector part 10 with respect to the direction of length. Each part of the divided power supply connector part 20 has a connector housing 21 in common with the connector housing 11 of the input-output connector part 10, so that the power supply connector part 20 is formed as an integral unit with the input-output connector part 10.

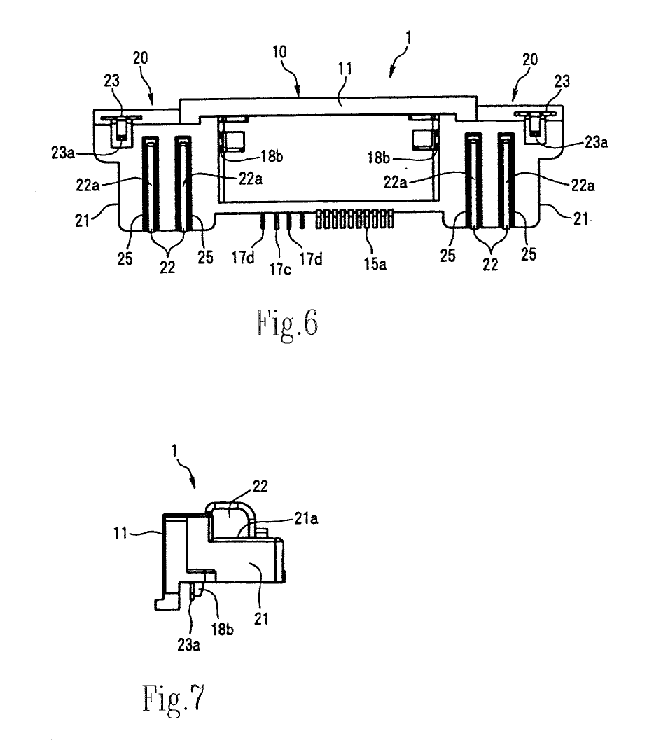

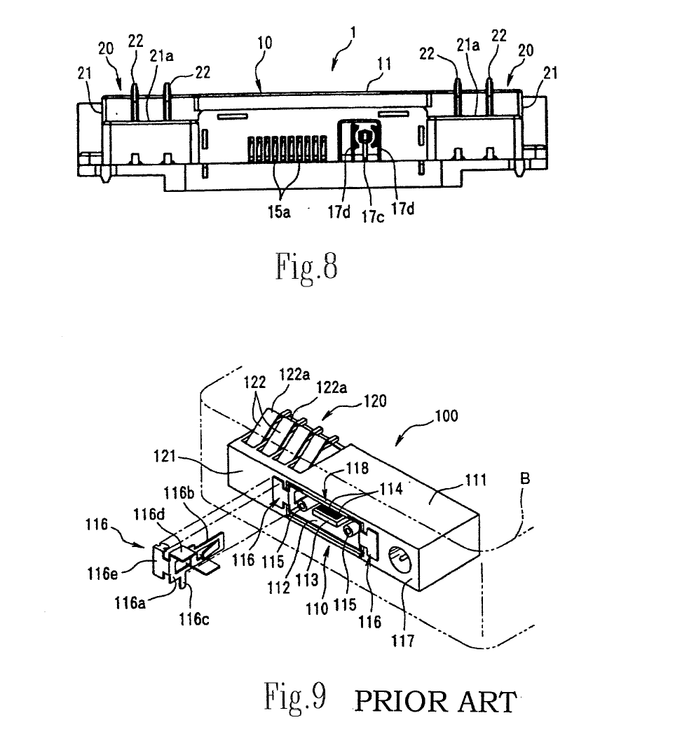

In each connector housing 21, two tab contacts 22 are disposed at a specified spacing along the direction of length. The tab contacts 22 make contact by being clamped by the elastic contact parts 5b (FIG. 1) of the power supply terminals 5 of the battery. Each tab contact 22 has a surface-mounting tine part 22a that is connected to a power conductive path on the circuit board by soldering (FIGS. 3 and 6). The respective tab contacts 22 are fastened to the connector housing 21 by press-fitting from the side of the undersurface so that the tab contacts 22 are exposed on the upper surface and rear surface where the step parts 21a are opened.

As a result of being connected by soldering to the power conductive paths on the circuit board, the tab contacts 22 make it possible to supply electrical power from the battery to the circuit board. The tab contacts 22 also function as solder pegs, which extend to the front and back of the connector housing 21 and fasten the electrical connector 1 to the circuit board. Accordingly, as a result of the power supply connector part 20 being uniformly divided and disposed on both sides of the input-output connector part 10 with respect to the direction of length, the tab contacts 22 that function as solder pegs are uniformly divided and disposed in a balanced manner with respect to the signal connector part 16 and coaxial connector part 17 located in the input-output connector part 10. Consequently, in cases where an external force is applied to the electrical connector 1, as a result of an impact or torsion, etc., damage to the tine parts 15a of the signal contacts 15 and tine parts 17c and 17d of the coaxial connector part 17 that might be caused by such an external force can be avoided.

Spaces 25 used for the formation of solder fillets are formed around the tab contacts 22 in the undersurfaces of the connector housings 21. When the tab contacts 22 are connected by soldering to the circuit board, solder fillets are formed around the respective tab contacts 22, so that the soldering strength is improved.

Opening parts 24 that open in the front surface are formed in the front walls 26 of the connector housings 21. Metal charging terminals 23, formed by stamping and bending a metal plate, are fastened to the front walls 26 by press-fitting from the side of the undersurface. A retention leg 23a is bent downward on the lower end and is fastened by soldering to the circuit board. The retention legs 23a are connected to the power conductive paths of the circuit board connected to the outside tab contacts 22 among the tab contacts 22. The legs 23a reinforce the electrical connector 1 when it is fastened to the circuit board. Accordingly, the battery can be charged via the power conductive paths and tab contacts 22 by causing the contacts of the charging device (not shown) to contact the charging terminals 23 via the opening parts 24 when the power supply terminals 5 of the battery contact the tab contacts 22.

When the portable telephone is used, the cover 4 is closed so that it fits the casing 2 of the portable telephone (FIG. 1) When the cover 4 is closed, the elastic contact parts 5b of the power supply terminals 5 of the battery clamp the tab contacts 22 of the power supply connector part 20 from above causing the power supply terminals 5 and tab contacts 22 to contact each other. As a result, power from the battery is supplied to the circuit board. In this case, the tab contacts 22 are exposed at the upper surface and rear surface where the step parts 21a of the connector housings 21 are opened, and portions on the side of the front surface 12 are supported by the connector housings 21. Accordingly, the power supply terminals 5 of the battery not only contact the tab contacts 22 from above, but can also contact the tab contacts 22 at an inclination from the rear, and the strength is reinforced.

Since tab contacts 22 which extend upward and in the forward-rearward direction are used as the power supply contacts of the power supply connector part 20 instead of leaf-type contacts, the contacts themselves are resistant to damage during and after contact with the power supply terminals 5. Even if some looseness of the battery in the vertical direction should occur, the contact pressure between the contacts in the power supply connector part and the power supply terminals on the power supply side is unaffected. Further, because the tab contacts 22 make contact with the elastic contact parts 5b of the power supply terminals 5 on both sides, the reliability of contact can be increased compared to a case where leaf-type contacts are used.

In cases where data communications are to be performed using a notebook-type personal computer (notebook PC), an external connector C coupled to the notebook PC via a cable can be connected to the input-output connector part 10. As a result, the circuit board of the notebook PC and the circuit board of the portable telephone are connected via the signal connector part 16, so that data communications are possible. Further, the coaxial connector part 17 can be used to inspect the circuit board inside the portable telephone or can be used to switch an antenna contained in the portable telephone to an antenna installed in an automobile.

While the present invention has been described in connection with the illustrated embodiments, it will be appreciated and understood that modifications may be made without departing from the true spirit and scope of the invention. For example, if the electrical connector 1 is used in an application where the connector is coupled to an external connector C and a power supply, the electrical connector 1 is not limited to use in a portable telephone. Further, the tab contacts 22 may have not only surface-mounting tine parts 22a that are connected by soldering to the circuit board, but also DIP tine parts that are connected by soldering to through-holes formed in the circuit board. The DIP tine parts have a function similar to that of the retention legs in terms of reinforcement when the electrical connector 1 is fastened to the circuit board.

I/we claim:

1. An electrical connector comprising:
an input-output connector part connected to an external connector;
a power supply connector part connected to a power supply and divided and disposed on both sides of the input-output connector part as an integral part of the input-output connector part;
the power supply connector part having tab contacts fastened to a connector housing that contact power supply terminals on the power supply and are connected to a circuit board; and
wherein the input-output connector part and the power supply connector part are formed into an integral unit by means of a common connector housing.

2. The electrical connector of claim 1 wherein the connector housing has a step part that opens on the upper surface and rear surface, and the tab contacts are fastened to the connector housing so that the tab contacts are exposed on the upper surface and rear surface on which the step part is opened.

3. The electrical connector of claim 1 wherein the connector housing has an external connector accommodating recess having a coaxial connector part and a signal connector part adjacently disposed to each other.

4. The electrical connector of claim 3 wherein the signal connector part has a plurality of signal contacts lined up at a specified pitch on a flat-plate part.

5. The electrical connector of claim 3 wherein the external connector accommodating recess has a shielding shell.

6. The electrical connector of claim 5 wherein the shielding shell is fastened to a peripheral edge of the external connector accommodating recess by press-fitting from the front so that the shell covers the signal connector part.

7. The electrical connector of claim 5 wherein the shielding shell has retention legs soldered to a grounding path of the circuit board.

8. The electrical connector of claim 5 wherein the shielding shell has a first external connector introduction guide part bent and folded downward on the front end of a lower sidewall of the shell and a second external connector introduction guide part bent and folded upward on the front end of an upper sidewall of the shell.

9. The electrical connector of claim 1 wherein the tab contacts have a surface-mounting tine part connected to a power conductive path on the circuit board by soldering.

10. The electrical connector of claim 1 wherein the tab contacts function as solder pegs that extend to the front and back of the connector housing and fasten the electrical connector to the circuit board.

11. The electrical connector of claim 1 wherein the tab contacts are soldered to the circuit board and solder fillets are formed around the tab contacts to increase the strength of the soldering.

12. The electrical connector of claim 1 wherein the connector housing has metal charging terminals formed by stamping and bending a metal plate fastened to the front walls of the housing by press-fitting from the side of the undersurface.

13. The electrical connector of claim 1 wherein the tab contacts may be contacted by battery power supply terminals from above or at an inclination from the rear so that the contact pressure between the contacts in the power supply connector part and the power supply terminals on the power supply side is unaffected.
